(19) United States
(12) Patent Application Publication
(10) Pub. No.: US 2010/0276803 A1
(43) Pub. Date: Nov. 4, 2010

(54) SEMICONDUCTOR DEVICE AND METHOD OF MANUFACTURING THE SAME

(75) Inventors: Takayuki Higuchi, Osaka (JP); Yoshihiro Tomura, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/771,507

(22) Filed: Apr. 30, 2010

(30) Foreign Application Priority Data
Apr. 30, 2009 (JP) 2009-111358

(51) Int. Cl. H01L 23/488; H01L 21/60

(52) U.S. Cl. 257/738; 438/615; 257/778; 257/E21.509; 257/E23.023

(57) ABSTRACT

A semiconductor element (101) includes an electrode section (102) and a bump (105), a circuit board (103) includes an electrode section (104) and a bump (106), and a conductive filler (108) having a lower melting point than the melting points of the bumps (105, 106) electrically bonds the bumps (105, 106) to each other.

### FIELD OF THE INVENTION

The present invention relates to a semiconductor device that bonds a semiconductor element and a circuit board via a bump, and a method of manufacturing the semiconductor device.

### BACKGROUND OF THE INVENTION

Today, electronic circuit boards have been used in various products.

Improvements in the performance of electronic circuit boards have been made on a daily basis and frequencies used on circuit boards have increased. Accordingly, flip-chip mounting that reduces impedance has become a mounting method suitable for electronic devices using high frequencies.

Furthermore, in portable devices, flip-chip mounting for mounting a semiconductor element directly onto a circuit board without packaging has been demanded for the purpose of reducing size and weight. In addition to flip-chips, packages such as a CSP (Chip Size Package) and a BGA (Ball Grid Array) have been increasingly used.

Moreover, in semiconductor elements, reduction in chip size and increase in pin count have been required with densification.

Conventionally, as a method of mounting a semiconductor element on a circuit board, a method of bonding a bump provided in a protruding manner on a semiconductor element onto an electrode section of a circuit board has been known. Solder is frequently used as the bump. During mounting of the semiconductor element, heat is applied to melt the solder bump and solder the bump to the electrode section of the circuit board.

In this case, since an oxide film on a solder surface inhibits soldering, the oxide film is physically removed or chemically removed using a flux. In addition, a gap between the semiconductor element and the circuit board is sealed by an underfill resin. The underfill resin encloses a solder junction to provide reinforcement and prevent invasion of foreign substances. A thermo-setting resin such as an epoxy resin is used as the underfill resin.

FIG. 4(A), FIG. 4(B), and FIG. 4(C) show a conventional process of mounting a semiconductor element onto a circuit board.

First, as shown in FIG. 4(A), an electrode section 402 and a bump 405i on the electrode section 402 are formed in a semiconductor element 401. An electrode section 404 and a bump 405c on the electrode section 404 are formed in a circuit board 403. The semiconductor element 401 and the circuit board 403 are arranged so that the bump 405i and the bump 405c oppose each other.

A flux 410 is applied to one or both of the bump 405i and the bump 405c. In FIG. 4(A), the flux 410 is applied to the bump 405i.

Next, the semiconductor element 401 and the circuit board 403 are brought close to each other so that the bump 405i and the bump 405c abut each other. In this state, the semiconductor element 401 and the circuit board 403 are heated to at least the melting point of solder of the bump 405i and the bump 405c.

As shown in FIG. 4(B), the bump 405i and the bump 405c that abut each other thus form a single bump 405 and the electrode section 402 and the electrode section 404 are electrically bonded by the bump 405.

Further, after the flux 410 remaining in the periphery of the electrode section 404 of the circuit board 403 is cleaned and removed, an underfill resin 409 made of an insulating resin is injected into a gap between the semiconductor element 401 and the circuit board 403. Subsequently, the underfill resin 409 is heated up to the curing temperature of the underfill resin 409 to complete a semiconductor device shown in FIG. 4(C).

Various measures have been taken in order to strengthen solder junctions. For example, in Japanese Patent Laid-Open No. 2003-100811, solder at a junction and a board are bonded by an insulating resin. In Japanese Patent Laid-Open No. 2008-034775, a solder junction is entirely covered by an insulating resin. To enable the removal of an oxide film on a solder surface, a method involving adding a flux component and the like to the insulating resin has been proposed.

In addition, Japanese Patent Laid-Open No. 2003-158153 proposes a method in which a flux is cured by heating and a reinforcement effect is provided in order to melt a bump and bond electrodes. Japanese Patent No. 3417281 proposes a method combining the methods described above.

In either method, since electrodes are electrically bonded by melting a bump (solder) itself, the height of the bump after bonding is reduced and the bump swells by the reduced height. As a result, spacing between a semiconductor element and a circuit board and spacing between the bumps after bonding (FIG. 4(B)) are reduced and a space (gap) formed between the semiconductor element and the circuit board becomes narrower. Furthermore, the space (gap) is further narrowed by an insulating resin covering the bumps and thus an underfill resin cannot be sufficiently injected.

In particular, with advancement in micro wiring of semiconductors in recent years, the narrow pitch of electrode sections and the area disposition of electrodes in semiconductor elements have further progressed. As a result, bumps have become smaller and gaps between semiconductor elements and circuit boards have become narrower, thereby making it further difficult to inject an underfill. Therefore, prevention of gaps between semiconductor elements and circuit boards from being narrowed has become a significant issue.

Regarding this issue, a proposal disclosed by Japanese Patent Laid-Open No. 2007-12953 is not effective in a case where bumps on both the side of a semiconductor element and the side of a circuit board are melted.

However, in the prior art, melting of bumps (solder) when bonding a semiconductor element and a circuit board disadvantageously narrows a gap between the semiconductor element and the circuit board, thereby inhibiting an underfill resin from being injected. An object of the present invention is to provide a semiconductor device that is less likely to inhibit an underfill resin from being injected after flip-chip mounting and includes a semiconductor element and a circuit board bonded via bumps, and a method of bonding the semiconductor element and the circuit board.

### DISCLOSURE OF THE INVENTION

A semiconductor device according to the present invention includes: a semiconductor element having a first electrode section and a first bump provided on the first electrode section; a circuit board having a second electrode section and a second bump provided on the second electrode section; and a junction for electrically bonding the first bump and the second bump, the junction having a lower melting point than the melting point of both the first bump and the second bump.

In addition, a method of manufacturing a semiconductor device according to the present invention includes the steps of: forming a paste that is a mixture of a conductive material and a thermo-setting insulating resin on at least one of a first bump formed on a semiconductor element and a second bump formed on a circuit board; abutting the first bump and the second bump on each other via the paste; and electrically bonding the abutting section of the first bump and the second bump with the solidified conductive material, in a state where the first bump and the second bump abut each other via the paste, by heating at a temperature not lower than the melting point of the conductive material and the curing temperature of the thermo-setting insulating resin and lower than the melting points of the first bump and the second bump.

### BRIEF DESCRIPTION OF THE DRAWINGS

FIG. 1A is a cross-sectional view of a process of a semiconductor mounting method according to a first embodiment of the present invention;

FIG. 1B is a cross-sectional view of a process of the semiconductor mounting method according to the first embodiment of the present invention;

FIG. 1C is a cross-sectional view of a process of the semiconductor mounting method according to the first embodiment of the present invention;

FIG. 2A is a cross-sectional view of a process of a semiconductor mounting method according to a second embodiment of the present invention;

FIG. 2B is a cross-sectional view of a process of the semiconductor mounting method according to the second embodiment of the present invention;

FIG. 2C is a cross-sectional view of a process of the semiconductor mounting method according to the second embodiment of the present invention;

FIG. 3A is a cross-sectional view of a process of a semiconductor mounting method according to a third embodiment of the present invention;

FIG. 3B is a cross-sectional view of a process of the semiconductor mounting method according to the third embodiment of the present invention;

FIG. 3C is a cross-sectional view of a process of the semiconductor mounting method according to the third embodiment of the present invention;

FIG. 4A is a cross-sectional view of a process of a semiconductor mounting method according to a conventional example;

FIG. 4B is a cross-sectional view of a process of the semiconductor mounting method according to the conventional example; and

FIG. 4C is a cross-sectional view of a process of the semiconductor mounting method according to the conventional example.

### DESCRIPTION OF THE EMBODIMENTS

Hereinafter, a method of manufacturing a semiconductor device according to the present invention will be described based on specific embodiments.

### First Embodiment

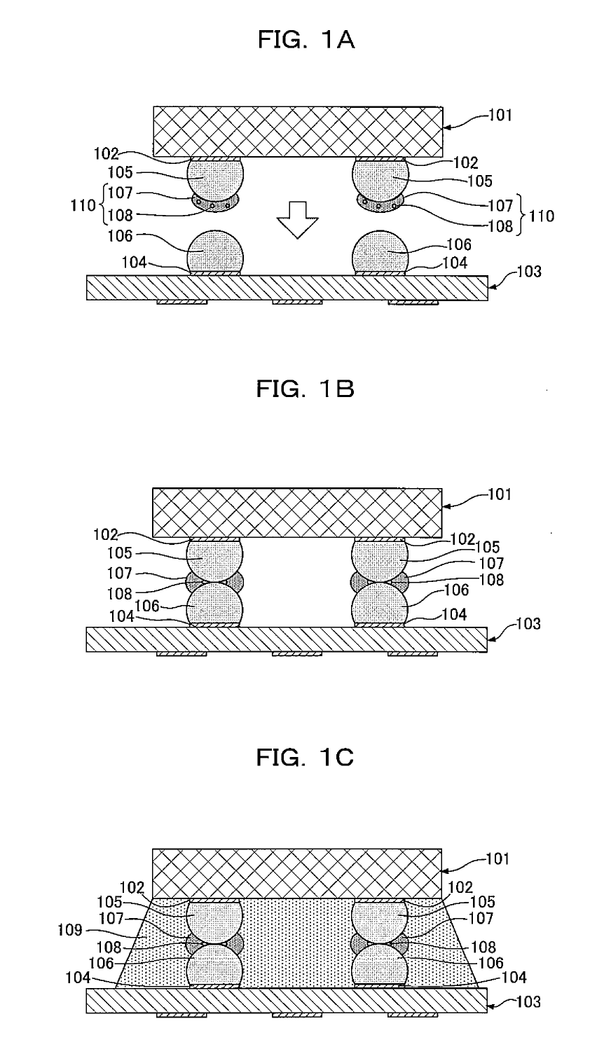

FIG. 1(A), FIG. 1(B), and FIG. 1(C) show a method of manufacturing a semiconductor device according to a first embodiment of the present invention.

First, as shown in FIG. 1(A), a semiconductor element 101 having a convex bump 105 formed on an electrode section 102 and a circuit board 103 having a convex bump 106 formed on an electrode section 104 are arranged so that the bump 105 and the bump 106 oppose each other. A conductive paste 110 obtained by mixing a conductive filler 108 into a thermo-setting resin 107 is applied to the end of one of the bumps 105 and 106 or to the ends of both of the bumps 105 and 106 by a means such as a transfer system. In FIG. 1(A), the conductive paste 110 is applied only to the bump 105.

The semiconductor element 101 and the circuit board 103 are brought close to each other so that the bump 105 and the bump 106 abut each other. Specifically, in an electronic component mounting apparatus, a bonding tool on a tip of a part holding member is used to position the semiconductor element 101, on which the bump 105 has been formed on the electrode section 102 in the previous step described above, with respect to the circuit board 103 prepared in the previous step described above, so that the electrode section 102 of the semiconductor element 101 is positioned above the corresponding electrode section 104 of the circuit board 103, while suctioning and holding the semiconductor element 101. Subsequently, the semiconductor element 101 is mounted on the circuit board 103. The positioning is performed using a known positional recognition operation. Heat is then applied for a predetermined amount of time at a temperature lower than the melting points of materials composing the bump 105 and the bump 106 and higher than the melting point of the conductive filler 108 of the conductive paste 110 and the curing temperature of the thermo-setting resin 107.

Before the thermo-setting resin 107 cures, the thermo-setting resin 107 melts and gathers around the abutting section of the bump 105 and the bump 106. The thermo-setting resin 107 then cures around the melted conductive filler 108 in the periphery of the abutting section of the bump 105 and the bump 106.

By stopping heating in this state, the conductive filler 108 solidifies in a state where the conductive filler 108 covers one of the periphery of the abutting section of the bump 105 and the bump 106 or a portion of the periphery of the abutting section of the bump 105 and the bump 106. The bump 105 and the bump 106 are brazed by the conductive filler 108 around the distal end sections that abut each other as shown in FIG. 1(B), resulting in a more secure electric connection. One of the periphery or a portion of the periphery of the solidified conductive filler 108 is covered and protected by the thermo-setting resin 107.

The present embodiment differs from the manufacturing methods of the prior art in that the bump 105 and the bump 106 are not melted and are in contact with each other at the distal end sections thereof.

As described above, a distance between the semiconductor element 101 and the circuit board 103 remains substantially unchanged before and after heating during mounting, and a gap between the semiconductor element 101 and the circuit board 103 can be secured. Furthermore, distances between the adjacent bumps 105 and bumps 106 also remain substantially unchanged before and after heating during mounting.

An underfill resin 109 made of an insulating resin is injected into the gap secured between the semiconductor element 101 and the circuit board 103 in this manner. Subsequently, the underfill resin is heated to the curing temperature of the underfill resin 109 to complete the semiconductor device shown in FIG. 1(C).

Moreover, an amount of the conductive filler 108 in the conductive paste 110 is preferably determined so that the conductive filler 108, once solidified, fits inside space in the periphery of the distal end portions of the bump 105 and the bump 106 abutting each other and does not spill out in the radial directions of the bump 105 and the bump 106.

Furthermore, an amount of the thermo-setting resin 107 in the conductive paste 110 is also preferably determined so that the thermo-setting resin 107, once solidified, fits inside space in the periphery of the solidified conductive filler 108 and does not spill out in the radial directions of the bump 105 and the bump 106.

As described above, since the bumps 105 and 106 are not bonded by melting, a flux does not have to be used unlike in the prior art, and thus cleaning and removing of a flux are not necessary. Therefore, the mounted semiconductor element 101 and the circuit board 103 can be reliably held by the thermo-setting resin 107 having been injected into larger space than in the prior art.

The electrode section 102 may be an Al pad electrode or an electrode which is made of one of Au and Cu and is formed by plating a metal on top of nickel plate or the like as a base.

The bump 105 is formed on the electrode section 102 using a solder ball mounter apparatus or the like. For example, one of a single tin alloy and a mixture of tin alloys can be used for the solder composition of the bump 105. Specifically, an alloy composition can be selected from a group consisting of Sn—Bi alloys, Sn—In alloys, Sn—Bi—In alloys, Sn—Ag alloys, Sn—Cu alloys, Sn—Ag—Cu alloys, Sn—Ag—Bi alloys, Sn—Cu—Bi alloys, Sn—Ag—Cu—Bi alloys, Sn—Ag—In alloys, Sn—Cu—In alloys, Sn—Ag—Cu—In alloys, and Sn—Ag—Cu—Bi—In alloys. In particular, an alloy composition selected from a group consisting of Sn—Ag alloys and Sn—Ag—Cu alloys is preferably used.

The bump 106 is formed on the electrode section 104. A method of forming the bump 106 or a material of the bump 106 may be the same as or different from the bump 105. For example, vapor deposition or a formation method using a solder paste may be employed.

For the circuit board 103, a ceramic multilayer board, a flexible printed circuit, a glass epoxy substrate, a glass polyimide substrate, an aramid nonwoven cloth epoxy substrate (for example, a resin multilayer board sold as “ALIVH”, a registered trademark, manufactured by Panasonic Corporation), or the like is used. In addition, the circuit board 103 may include the same base material as the semiconductor element such as Si.

While an electrode section formed by plating with Ni over Cu and then flash-plating with Au on a surface of the Ni plate is used as the electrode section 104 on the circuit board 103, the material of the electrode section 104 may be the same as or different from the material of the electrode section 102 of the semiconductor element 101.

The thermo-setting resin 107 contains an insulating resin, a curing agent, and an activator having an oxide-film removing effect as primary components. A viscosity-adjusting/thixotropy-imparting additive can be appropriately added by choice.

The underfill resin 109 can contain various types of resins such as epoxy resin, urethane resin, acrylic resin, polyimide resin, polyamide resin, bismaleimide, phenolic resin, polyester resin, silicon resin, and oxetane resin. These resins may be used independently or by a combination of two or more types. Among the aforementioned resins, epoxy resin is particularly favorable.

An epoxy resin can be selected from a group consisting of bisphenol-type epoxy resin, polyfunctional epoxy resin, flexible epoxy resin, brominated epoxy resin, glycidylester-type epoxy resin, and high-molecular weight epoxy resin.

For example, bisphenol A-type epoxy resin, bisphenol F-type epoxy resin, bisphenol S-type epoxy resin, biphenyl-type epoxy resin, naphthalene-type epoxy resin, phenol novolac-type epoxy resin, and cresol novolac-type epoxy resin can be favorably used. Epoxy resins obtained by modifying the aforementioned epoxy resins can also be used. The epoxy resins may be used independently or by a combination of two or more types.

As a curing agent to be used in combination with the thermo-setting resins described above, a compound can be selected from a group consisting of thiol compounds, modified amine compounds, polyfunctional phenol compounds, imidazole compounds, and acid anhydride compounds. The compounds may be used independently or by a combination of two or more types. A favorable curing agent is selected depending on the usage environment and application of the conductive paste.

As an activator having an oxide-film removing effect, an activator is used which has reduction ability to remove and melt/bond an oxide film on an electrode or alloy particle surface, which is an adherend, in a temperature range in which the conductive paste 110 is heated and cured. The activator can contain rosin or modified rosin described in JIS Z3283 as a base resin and, as needed, haloid salt of amine, organic acid or amine organic salt as an activator component.

Examples of the activator include: lauric acid, myristic acid, palmitinic acid, and stearic acid that are saturated aliphatic monocarboxylic acids; crotonic acid that is an unsaturated aliphatic monocarboxylic acid; oxalic acid, malonic acid, succinic acid, glutaric acid, adipic acid, pimelic acid, suberic acid, azelaic acid, and sebacic acid that are saturated aliphatic dicarboxylic acids; maleic acid and fumaric acid that are unsaturated aliphatic dicarboxylic acids; phthalaldehydic acid, phenylbutyrate, phenoxyacetic acid, and phenylpropionic acid that are aromatic carboxylic acids; diglycol acid, thiodiglycolic acid and dithiodiglycolic acid that are ether dicarboxylic acids; ethylamine hydrochloride, diethylamine hydrochloride, dimethylamine hydrochloride, cyclohexylamine hydrochloride, triethanolamine hydrochloride, and glutamic acid hydrochloride that are amine hydrochlorides; diethylamine hydrobromide and cyclohexylamine hydrobromide that are amine hydrobromides; as abietic acid; and ascorbic acid.

Viscosity-adjusting/thixotropy-imparting additives can be either inorganic or organic. For example, silica and alumina are used for the inorganic additive, and solid epoxy resin, low-molecular-weight amide, polyester series, and an organic derivative of castor oil are used for the inorganic additive. These additives may be used independently or by a combination of two or more types.

For the conductive filler 108, for example, a solder material that is a single tin alloy or a mixture of tin alloys can be used. Specifically, an alloy composition can be selected from a group consisting of Sn—Bi alloys, Sn—In alloys, Sn—Bi—In alloys, Sn—Ag alloys, Sn—Cu alloys, Sn—Ag—Cu alloys, Sn—Ag—Bi alloys, Sn—Cu—Bi alloys, Sn—Ag—Cu—Bi alloys, Sn—Ag—In alloys, Sn—Cu—In alloys, Sn—Ag—Cu—In alloys, and Sn—Ag—Cu—Bi—In alloys. In particular, an alloy composition is favorably selected from a group consisting of Sn42Bi58, Sn48In52, Sn16Bi56In28, SnAg3Cu0.5, and SnAg3.5Bi0.5In8.

However, an alloy composition to be selected has to have a melting point equal to or lower than the melting points of the solders selected as materials of the bumps 105 and 106. Preferably, the alloy composition has a melting point that is approximately at least 10° C. lower than the melting point of the solder selected as the materials of the bumps 105 and 106.

In addition, the alloy composition of the conductive filler 108 is selected from alloy compositions having a melting point equal to or higher than a temperature at which curing of the thermo-setting resin 107 starts. Favorably, the alloy composition of the conductive filler 108 has a melting point that is approximately 10° C. to 20° C. higher than the temperature at which curing of the thermo-setting resin 107 starts.

Alloy particles are supplied in the form of fine particles. Preferably, alloy particles are supplied in the form of spherical particles. Alloy particles in the form of spherical particles can be obtained by preparing an alloy with a predetermined composition and subsequently performing granulation through an operation such as atomization and tumbling granulation. The spherical particles generally may have particle diameters of approximately 1 to 50 μm and, more preferably, approximately 10 to 40 μm.

Regarding the mixture fraction of the thermo-setting resin 107 and the conductive filler 108, for example, when the thermo-setting resin 107 is assumed to have approximately 100 parts by weight, the conductive filler 108 may be set to have approximately 1 to 50 parts by weight. However, the present invention is not limited to the aforementioned mixture fraction and the mixture fraction can be selected as appropriate.

Generally, for the underfill resin 109, a resin commercially available as an underfill resin or a molding agent suffices, and the same resin as the thermo-setting resin 107 may also be used. Preferably, an activator having an oxide-film removing effect is not added.

### Second Embodiment

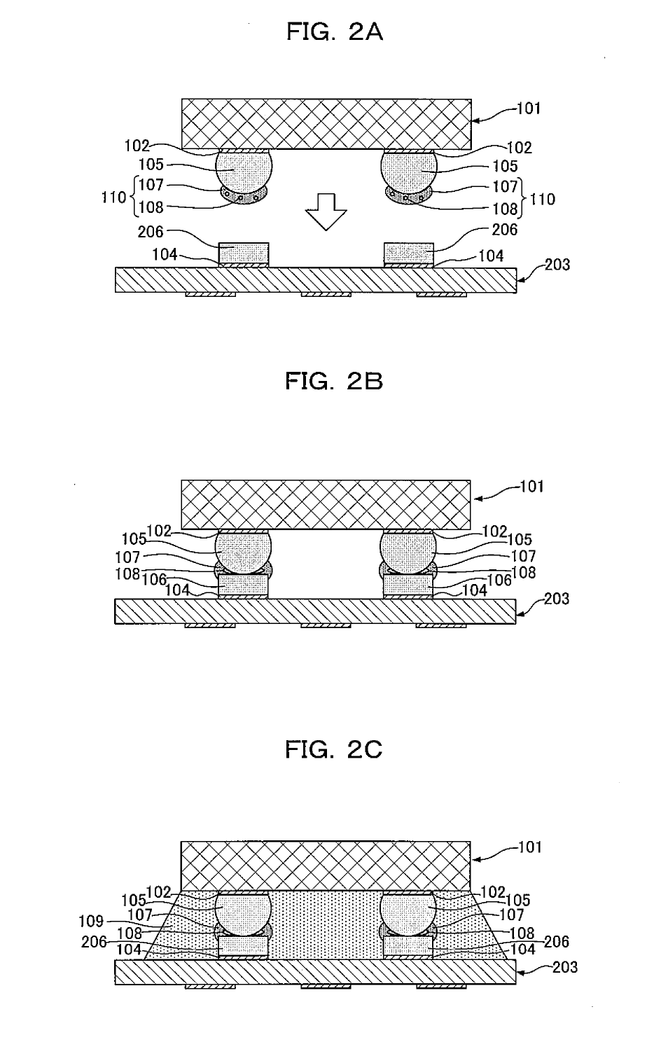

FIG. 2(A), FIG. 2(B), and FIG. 2(C) show a method of manufacturing a semiconductor device according to a second embodiment of the present invention.

In the first embodiment, both of the bumps 105 and 106 were convex-shaped. However, in the second embodiment, a bump 206 on the side of a circuit board is tabularly formed. Otherwise, the second embodiment has the same configuration as the first embodiment.

As shown in FIG. 2(A), a semiconductor element 101 having a convex bump 105 formed on an electrode section 102 and a circuit board 203 having the tabular bump 206 formed on an electrode section 104 are arranged so that the bump 105 and the bump 206 oppose each other. A conductive paste 110 obtained by mixing a conductive filler 108 into a thermo-setting resin 107 is applied to the end of one of the bumps 105 and 206 or to the ends of both of the bumps 105 and 206 by a means such as a transfer system. In FIG. 2(A), the conductive paste 110 is applied only to the bump 105.

The bump 206 on the side of the circuit board 203 differs from the bump 106 in formation method and shape. Specifically, the bump 206 is formed so as to be substantially tabular using an electrolytic method or an electroless method by solder plating. The composition of the bump 206 may be the same as or different from the bump 105.

The circuit board 203 and the semiconductor element 101 are arranged as shown in FIG. 2(B) so that the tip of the convex bump 105 abuts the plane of the tabular bump 206. By heating in this state and subsequently stopping heating, the conductive filler 108 solidifies in the periphery of the abutting section of the bump 105 and the bump 206, and the thermo-setting resin 107 cures around the solidified conductive filler 108. Accordingly, the bumps 105 and 206 are electrically and physically bonded to each other.

The solidified conductive filler 108 and the cured thermo-setting resin 107 substantially fit in the outlines of the bumps 105 and 206. Therefore, as shown in FIG. 2(C), a sufficient space (gap) to be injected an underfill resin 109 can be secured between the semiconductor element 101 and the circuit board 203.

### Third Embodiment

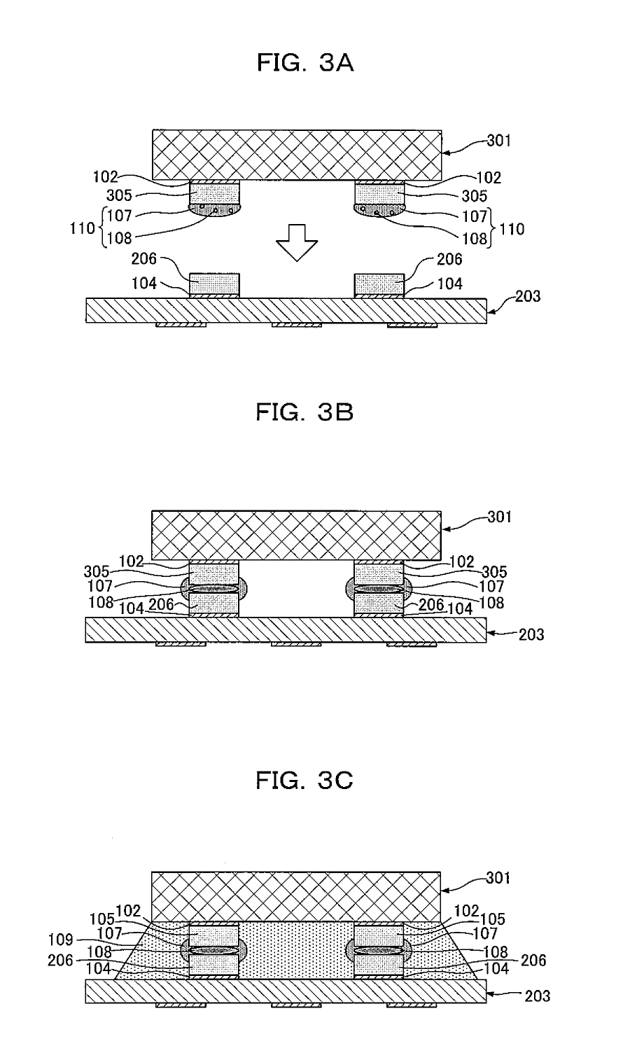

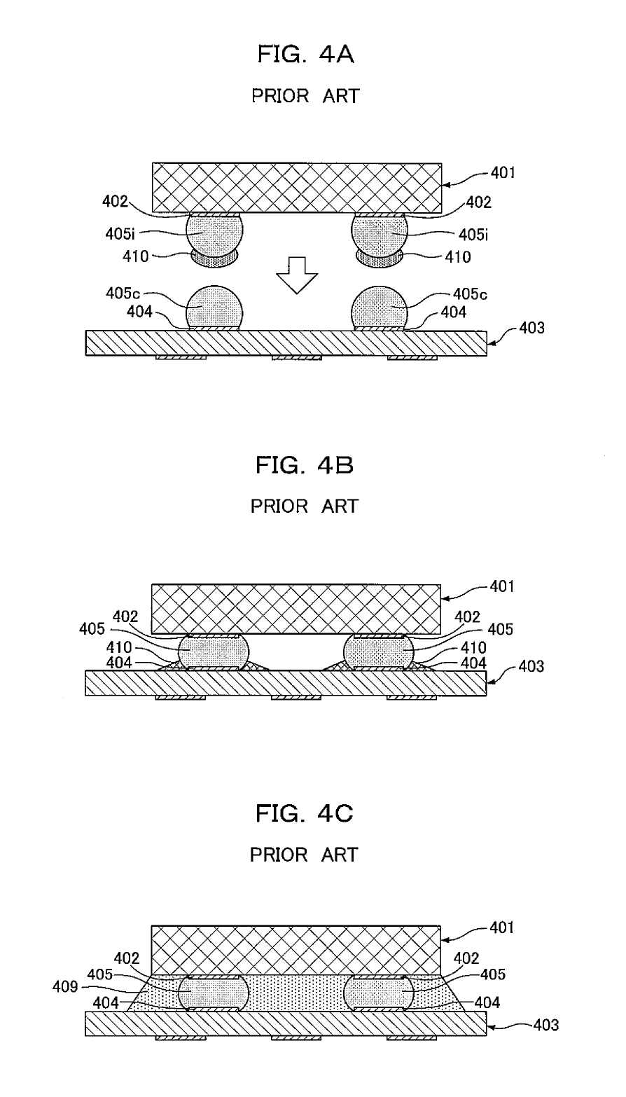

FIG. 3(A), FIG. 3(B), and FIG. 3(C) show a method of manufacturing a semiconductor device according to a third embodiment of the present invention.

In the first embodiment, both of the bumps 105 and 106 were convex-shaped. However, in the present third embodiment, both a bump 305 on the side of a semiconductor element and a bump 206 on the side of a circuit board are tabularly formed. Otherwise, the third embodiment has the same configuration as the first embodiment.

As shown in FIG. 3(A), a semiconductor element 301 having the tabular bump 305 formed on an electrode section 102 and a circuit board 203 having the tabular bump 206 formed on an electrode section 104 are arranged so that the bump 305 and the bump 206 oppose each other. A conductive paste 110 obtained by mixing a conductive filler 108 into a thermo-setting resin 107 is applied to the end of one of the bumps 305 and 206 or to the ends of both of the bumps 305 and 206 by a means such as a transfer system. In FIG. 3(A), the conductive paste 110 is applied only to the bump 305.

Since the bumps 305 and 206 to be bonded to each other are tabularly formed by solder plating, as shown in FIG. 3(B), the conductive filler 108 solidifies tabularly between the primary surfaces of the bumps 305 and 206. In other words, the bumps 305 and 206 are bonded across the entire surfaces by the conductive filler 108 having solidified on the respective primary surfaces. A junction formed by the solidified conductive filler 108 is covered by the cured conductive filler 108.

In this case, the conductive filler 108 substantially fits in the outlines of the solidified bumps 305 and 206. The cured conductive filler 108 slightly spills out of the outer shapes of the bumps 305 and 206. Therefore, as shown in FIG. 3(C), a sufficient space (gap) to be injected an underfill resin 109 can be secured between the semiconductor element 301 and the circuit board 203. Moreover, since the bumps 305 and 206 are bonded over the entire surfaces by the conductive filler 108, more secure electric bonding can be achieved.

Hereinafter, specific examples and comparative examples will be compared to evaluate the results according to the respective embodiments described above.

Here, the specific example of the first embodiment will be denoted as a first example, the specific example of the second embodiment will be denoted as a second example, and the specific example of the third embodiment will be denoted as a third example.

The semiconductor element, circuit board, and conductive paste described below and used in the first to third examples and the respective comparative examples were the same.

A semiconductor element having a thickness of 100 μm and a total of 160 Al pad electrodes (each 85×85 μm in size) arranged across an entire 8 mm square Si plane were used. Electrode sections of the semiconductor element were respectively arranged at intervals of 180 μm or greater.

A 340 μm-thick ALIVH board was used as the circuit board, and 100 μm square electrodes formed by Ni plating and flash Au plating over a Cu base were used at positions corresponding to the electrodes of the semiconductor element. The centers of the electrodes of the circuit board and the centers of the electrodes of the semiconductor element were designed so as to coincide with each other.

The conductive paste used was obtained by mixing, into a one-component thermo-setting resin obtained by mixing a latent imidazole curing agent into a bisphenol A type epoxy resin, a conductive filler composed of spherical SnAgBiIn alloy particles (melting point: approximately 195° C.) with an average particle diameter of 21 μm and an activator primarily containing an abietic acid with an oxide-film removing effect.

After forming the semiconductor device according to the first to third examples and the comparative examples described below, an insulating resin (underfill resin) was injected into a gap between the semiconductor device and the circuit board. The results of measurements of an interval between the semiconductor device and the circuit board after heating and curing are shown in “Table 1”.

Regarding filling of the underfill resin, voids (air bubbles) were observed using an SAT (scanning acoustic tomograph), and the filing was evaluated as “P (poor)” when at least 10 voids were confirmed, “E (excellent)” when at most 5 voids were confirmed, and otherwise, “F (fair)”.

### First Comparative Example

A bump 105 that is a solder ball having a diameter of 85 μm and a SnAgCu composition (melting point: 218° C.) was formed using a solder ball mounter apparatus on the electrode section 102 of a semiconductor element 101. Meanwhile, a bump 106 having a height of 80 μm and a SnAgCu composition (melting point: 218° C.) was formed using a solder paste printing method on the electrode section 104 of a circuit board 103. After transferring a flux 410 onto the bump 105 of the semiconductor element 101, the bump 105 of the semiconductor element 101 was aligned with the bump 106 of the circuit board 103 by a mounting machine and heated to 230° C.

### First Example

In the same manner as in the first comparative example, bumps 105 and 106 were formed, and after transferring the conductive paste 110 onto the bump 105 of the semiconductor element, the bump 105 of the semiconductor element was aligned with the bump 106 of the circuit board 103 by a mounting machine and heated to 200° C.

### Second Comparative Example

A bump 105 that is a solder ball having a diameter of 85 μm and a SnAg composition (melting point: 220° C.) was formed using a solder ball mounter apparatus on the electrode section 102 of the semiconductor element 101. Meanwhile, a solder plated bump 206 having a height of 50 μm and a SnAg composition (melting point: 220° C.) was formed by electrolytic plating on the electrode section 104 of the circuit board 203. After transferring the flux 410 onto the bump 105 of the semiconductor element 101, the bump 105 of the semiconductor element 101 was aligned with the bump 206 of the circuit board 203 by a mounting machine and heated to 230° C.

### Second Example

In the same manner as in the second comparative example, bumps 105 and 206 were formed, and after transferring the conductive paste 110 onto the bump 105 of the semiconductor element 101, the bump 105 of the semiconductor element 101 was aligned with the bump 206 of the circuit board 203 by a mounting machine and heated to 200° C.

### Third Comparative Example

A solder plated bump 305 having a height of 50 μm and a SnAg composition (melting point: 220° C.) was formed by electrolytic plating on the electrode section 102 of the semiconductor element 301. Meanwhile, a solder plated bump 206 having a height of 50 μm and a SnAg composition (melting point: 220° C.) was formed by electrolytic plating on the electrode section 104 of the circuit board 203. After transferring the flux 410 onto the bump 305 of the semiconductor element 301, the bump 305 of the semiconductor element 301 was aligned with the bump 206 of the circuit board 203 by a mounting machine and heated to 230° C.

### Third Example

In the same manner as in the third comparative example, solder plated bumps 305 and 206 were formed, and after transferring the conductive paste 110 onto the bump 305 of the semiconductor element 301, the bump 305 of the semiconductor element 301 was aligned with the bump 206 of the circuit board 203 by a mounting machine and heated to 200° C.

TABLE 1

| | Interval between | | |
|---|---|---|---|
| | semiconductor | | |
| | device and circuit | Continuity | Underfill |
| | board [μm] | check | filling |
| First | 100 | E | F |
| comparative | | | |
| example | | | |
| First example | 150 | E | E |
| Second | 90 | E | F |
| comparative | | | |
| example | | | |
| Second example | 125 | E | E |
| Third | 75 | E | P |
| comparative | | | |
| example | | | |
| Third example | 100 | E | E |

From “Table 1”, it is noted that the interval between the semiconductor element and the circuit board was large in any of the examples as compared to the comparative examples of the prior art structures, and improvement effects of underfill resin filling can also be observed.

The present invention contributes to reduction in size and weight and improvement in reliability of electronic circuits to be used in various portable devices or the like.

What is claimed is:

1. A semiconductor device comprising: a semiconductor element having a first electrode section and a first bump provided on the first electrode section;
a circuit board having a second electrode section and a second bump provided on the second electrode section; and
a junction for electrically bonding the first bump and the second bump, the junction having a lower melting point than a melting point of both the first bump and the second bump.

2. The semiconductor device according to claim 1, further comprising
a thermo-setting insulating resin section for covering one of a periphery of and a part of the junction.

3. The semiconductor device according to claim 1, wherein
the first bump and the second bump are both convexly formed and abut each other at distal end portions thereof to constitute an abutting section, and
the junction is formed so as to cover one of a periphery and a part of the abutting section.

4. The semiconductor device according to claim 1, wherein
one of the first bump and the second bump is convexly formed and an other is formed so as to have a tabular tip, a distal end portion of the convexly formed first bump abutting a tabular surface of the bump formed to have the tabular tip formed to constitute an abutting section, and
the junction is formed so as to cover one of a periphery and a part of the abutting section.

5. The semiconductor device according to claim 1, wherein
the first bump and the second bump are both formed so as to have a tabular tip and abut each other at tabular surfaces thereof to constitute an abutting section, and
the junction is formed so as to cover one of a periphery and a part of the abutting section.

6. A method of manufacturing a semiconductor device comprising the steps of:
forming a paste that is a mixture of a conductive material and a thermo-setting insulating resin on at least one of a first bump formed on a semiconductor element and a second bump formed on a circuit board;
abutting the first bump and the second bump on each other via the paste; and
electrically bonding an abutting section of the first bump and the second bump with the solidified conductive material, in a state where the first bump and the second bump abut each other via the paste, by heating at a temperature not lower than a melting point of the conductive material and a curing temperature of the thermo-setting insulating resin and lower than melting points of the first bump and the second bump.

7. The method of manufacturing a semiconductor device according to claim 6, wherein
in the step of electrically bonding the abutting section of the first bump and the second bump with the solidified conductive material, the thermo-setting insulating resin is cured so as to cover one of a periphery and a part of the abutting section of the first bump and the second bump.

8. A method of manufacturing a semiconductor device comprising the steps of:
forming a paste that is a mixture of a conductive material and a thermo-setting insulating resin on at least one of a first bump formed on a semiconductor element and a second bump formed on a circuit board;
abutting the first bump and the second bump on each other via the paste;
electrically bonding an abutting section of the first bump and the second bump with the solidified conductive material in a state where the first bump and the second bump abut each other via the paste by heating at a temperature higher than a melting point of the conductive material and a curing temperature of the thermo-setting insulating resin and lower than melting points of the first bump and the second bump; and
injecting a thermo-setting insulating resin section for covering one of a periphery and a part of the junction.

9. The semiconductor device according to claim 1, wherein
the junction is composed of a thermo-setting resin and a conductive filler, and the first bump and the second bump are electrically connected by the conductive filler.

10. The semiconductor device according to claim 1, wherein
the first bump and the second bump are both tabularly formed by solder plating and abut each other at tabular surfaces thereof to constitute an abutting section, and
the junction is formed so as to cover one of a periphery and a part of the abutting section.

11. The semiconductor device according to claim 1, wherein
the first bump and the second bump are not melted and are in contact with each other at distal end portions thereof.
